(19) United States
(12) Patent Application Publication
(10) Pub. No.: US 2011/0095433 A1
(43) Pub. Date: Apr. 28, 2011

(54) CONDUCTIVE FILM, METHOD OF MANUFACTURING THE SAME, SEMICONDUCTOR DEVICE AND METHOD OF MANUFACTURING THE SAME

(75) Inventors: Michio HORIUCHI, Nagano-shi (JP); Yasue TOKUTAKE, Nagano--shi (JP); Yuichi MATSUDA, Nagano-shi (JP); Tsuyoshi KOBAYASHI, Nagano-shi (JP); Tatsuaki DENDA, Nagano-shi (JP)

(73) Assignee: Shinko Electric Industries Co., Ltd., Nagano-shi (JP)

(21) Appl. No.: 12/908,943

(22) Filed: Oct. 21, 2010

(30) Foreign Application Priority Data
Oct. 22, 2009 (JP) 2009-243030

(51) Int. Cl. H01L 23/535; H05K 1/02; H01L 21/768; B05D 5/12

(52) U.S. Cl. 257/773; 174/258; 438/667; 427/58; 257/E23.168; 257/E21.585

(57) ABSTRACT

There is provided a method of manufacturing a conductive film. The method includes: (a) providing an anodized layer having a plurality of through holes extending therethrough in its thickness direction; (b) forming a plurality of linear conductors by filling each of the through holes with a conductive material; (c) forming protection layers on both surfaces of the anodized layer; (d) removing the anodized layer to form a plurality of gaps between the linear conductors; (e) forming an organic insulation layer between the protection layers to fill the gaps with the organic insulation layer; and (f) removing the protection layers.

This application claims priority from Japanese Patent Application No. 2009-243030, filed on Oct. 22, 2009, the entire contents of which are herein incorporated by reference.

### BACKGROUND

1. Technical Field

The present disclosure relates to a conductive film, a method of manufacturing the same, a semiconductor device and a method of manufacturing the same.

2. RELATED ART

For a connecting structure of a semiconductor device, JP-A-9-293759 discloses a technique using an uncured resin as a connecting member.

JP-A-2000-223534 discloses a technique using a resin layer made of an anisotropically conductive paste as a connecting member.

JP-A-2003-31617 discloses a technique using a mixture of conductive particles and a synthetic resin as a connecting member.

JP-A-10-308565 and JP-A-9-331134 disclose a wiring board in which metal wires are buried within a fired columnar porous body made of an inorganic insulation material in parallel with an axis of the columnar body.

JP-A-10-189096 discloses a board bonding film having a resin material and conductive portions formed by filling a metal in connecting holes penetrating through the resin material in its thickness direction, wherein the resin material has an electric insulation property and an adhesiveness through a heating process.

According to the disclosure of the above mentioned documents, it is considered that it is possible to manufacture a semiconductor device in which electronic components (e.g., semiconductor elements) are mounted on the wiring board. Since the wiring board in the packaging structure is used to mount electronic components including the semiconductor element, it is called a semiconductor package, or simply, a package. In addition, in the present embodiment, a structure including the semiconductor element is referred to as a semiconductor device.

As the connecting member in the case of packaging, for example, an anisotropic conductive film (ACF) is used in which conductive balls having a size of several micrometers are diffused in a thermosetting resin. By providing an anisotropic conductive film having conductive balls therein between the wiring board and the semiconductor element and heating and pressing them, the thermosetting resin is fluidized, and the conductive balls are inserted between the connecting terminal of the wiring board and the connecting terminal of the semiconductor element, so that the wiring board and the semiconductor element are electrically connected to each other.

However, as semiconductor devices are miniaturized and high-functioned, a connecting terminal of the semiconductor element becomes finer in size and narrower in pitch (finer pitch). In this manner, if the semiconductor element having a connecting terminal having a finer size and a narrower pitch is packaged on the wiring board using the anisotropic conductive film having the conductive balls, the conductive balls are pressed and extracted from the space between the connecting terminal of the semiconductor element and the connecting terminal of the wiring board that are facing each other and make contact with the neighboring connecting terminal, so that an electrical short may occur between the connecting terminals. Therefore, in the semiconductor device in which a plurality of components are connected (e.g., packaged), a connection reliability and a product yield may be degraded.

It is envisaged that such a problem in the connecting terminals is influenced by the sizes of the connecting terminal and the conductive ball, flatness or thermal expansion of the anisotropic conductive film during the packaging. Through diligent study, the inventors discovered that, when an anisotropic conductive film having typical conductive balls is used in the semiconductor element having a connecting terminal in an area array state, and the pitch between the connecting terminals is equal to or smaller than 0.1 mm, appropriate connection is difficult.

### SUMMARY OF THE INVENTION

Exemplary embodiments of the present invention address the above disadvantages and other disadvantages not described above. However, the present invention is not required to overcome the disadvantages described above, and thus, an exemplary embodiment of the present invention may not overcome any disadvantages

According to one or more illustrative aspects of the invention, there is provided a method of manufacturing a conductive film. The method includes: (a) providing an anodized layer having a plurality of through holes extending therethrough in its thickness direction; (b) forming a plurality of linear conductors by filling each of the through holes with a conductive material; (c) forming protection layers on both surfaces of the anodized layer; (d) removing the anodized layer to form a plurality of gaps between the linear conductors; (e) forming an organic insulation layer between the protection layers to fill the gaps with the organic insulation layer; and (f) removing the protection layers.

Other aspects and advantages of the present invention will be apparent from the following description, the drawings and the claims.

### BRIEF DESCRIPTION OF THE DRAWINGS

FIG. 1 is a cross-sectional view schematically illustrating a conductive film during a manufacturing process according to an embodiment of the present invention;

FIG. 2 is a cross-sectional view schematically illustrating a conductive film during a manufacturing process subsequent to FIG. 1;

FIG. 3 is a cross-sectional view schematically illustrating a conductive film during a manufacturing process subsequent to FIG. 2;

FIG. 4 is a cross-sectional view schematically illustrating a conductive film during a manufacturing process subsequent to FIG. 3;

FIG. 5 is a cross-sectional view schematically illustrating a conductive film during a manufacturing process subsequent to FIG. 4;

FIG. 6 is a cross-sectional view schematically illustrating a conductive film during a manufacturing process subsequent to FIG. 5;

FIG. 7 is a SEM image illustrating surface morphology of an anodized layer having a plurality of through holes therein;

FIG. 8 is a SEM image illustrating surface morphology of an anodized layer having a plurality of linear conductors therein;

FIG. 9 is a perspective view schematically illustrating the plurality of linear conductors;

FIG. 10 is a cross-sectional view schematically illustrating a semiconductor device during a manufacturing process according to the embodiment of the present invention;

FIG. 11 is a cross-sectional view schematically illustrating a semiconductor device during a manufacturing process subsequent to FIG. 10;

FIG. 12 is an enlarged cross-sectional view schematically illustrating a main part of the semiconductor device shown in FIG. 11; and

FIG. 13 is a cross-sectional view schematically illustrating a semiconductor device during a manufacturing process according to another embodiment of the present invention.

### DETAILED DESCRIPTION OF EXEMPLARY EMBODIMENTS

Hereinafter, exemplary embodiments of the present invention will be described with reference to the accompanying drawings. In all the drawings for the explanation of the embodiments, the members having the same functions are represented by the same reference numerals, and repeated description thereof will be omitted.

### First Embodiment

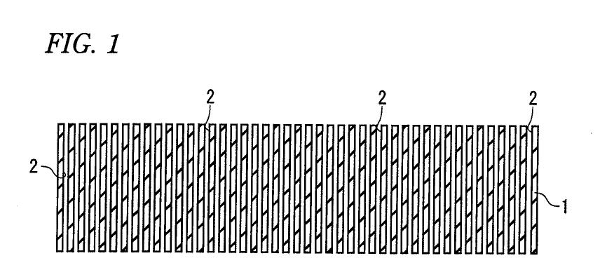

A method of manufacturing a conductive film according to the present embodiment will be now described. First of all, as shown in FIG. 1, an anodized layer 1 having a plurality of through holes 2 extending therethrough in the thickness direction is prepared. When aluminum (Al) is used as the metal, aluminum oxide which is an inorganic insulation layer is formed as the anodized layer 1 by anodizing aluminum.

For example, firstly, an aluminum plate having a size of 10 mm×10 mm, of which one surface is insulated with a film is prepared, and the surface of the aluminum plate is cleaned. Then, the aluminum plate is used as the positive electrode by immersing it in an electrolyte liquid such as an aqueous solution of a sulfuric acid or an oxalic acid, and an electric current flows (by applying a pulse voltage) through a platinum (Pd) plate arranged to face the aluminum plate as a negative electrode, so that a porous layer (the holes 2) can be formed on the surface of the aluminum plate. Then, the porous layer is separated from the remaining aluminum plate, for example, through cutting to form the through holes in the porous layer. As a result, it is possible to obtain an anodized layer 1 having multiple pores extending therethrough in the thickness direction, i.e., a plurality of fine through holes 2.

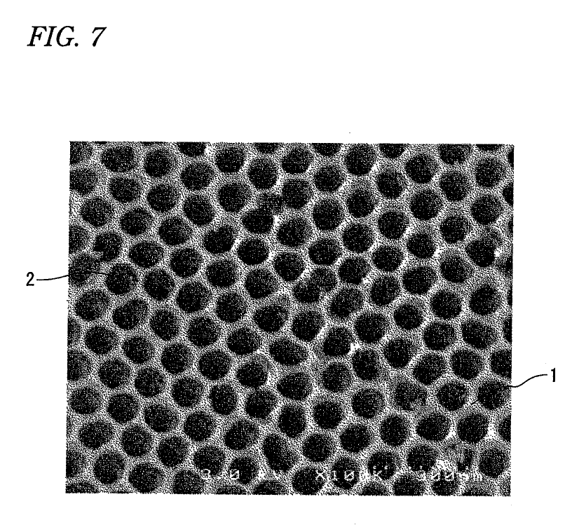

FIG. 7 is a SEM image illustrating surface morphology of the anodized layer 1 where a plurality of through holes 2 are provided. As shown in FIG. 7, it can be seen that pores having a honeycomb structure are formed on the surface of the anodized layer 1 through self-organization.

In the anodizing of aluminum, the aluminum oxide layer is formed by electrochemically oxidizing the surface of aluminum. In the anodizing, it is possible to adjust the thickness of the anodized layer 1 or a diameter or a pitch of the through holes 2 depending on conditions such as the type of the electrolyte liquid, voltage, and time. Here, the pitch of the through holes 2 is defined as a distance between centers of the adjacent through holes. For example, the thickness (the depth of the through holes 2) of the anodized layer 1 may be set to about 70 μm to about 180 μm the diameter of the through hole 2 may be set to about 30 nm to about 1000 nm, and the pitch of the through hole 2 may be set to about 40 nm to about 1200 nm. In this manner, the aspect ratio (a ratio between the depth and the diameter of hole) of the through holes 2 in the anodized layer 1 is set to be high.

Through the aforementioned process, the anodized layer 1 where a plurality of through holes 2 are densely arranged in parallel with the thickness direction is formed within a plane having a size of approximately 10 mm×10 mm.

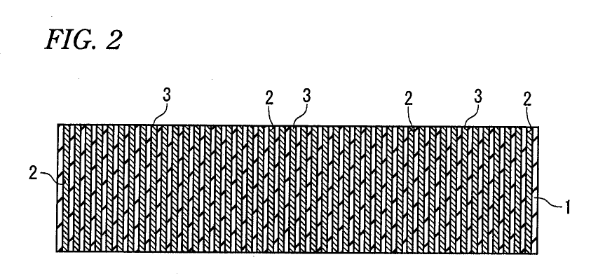

Subsequently, as shown in FIG. 2, a plurality of linear conductors 3 are formed by filling each of the through holes 2 with a conductive material. Then, the surface of the anodized layer 1 is polished to obtain flatness of the surface of the anodized layer 1 or uniformity of the length of the linear conductor 3.

For example, the fine through holes 2 may be filled with a conductive material using an electrolytic plating in which an electrode is provided on one surface of the anodized layer 1. Thus, the linear conductor 3 is made of such a conductive material. As a conductive material, copper (Cu), nickel (Ni) may be used in consideration of electric conductivity, corrosion resistance, or the like. As a result, it is possible to form the anodized layer 1 having a plurality of linear conductors 3 extending therethrough in the thickness direction. In addition, in order to improve the anti-corrosion property of the anodized layer 1, the internal side of the through holes 2 is covered by a barrier film, and a conductive material such as copper may be filled therein.

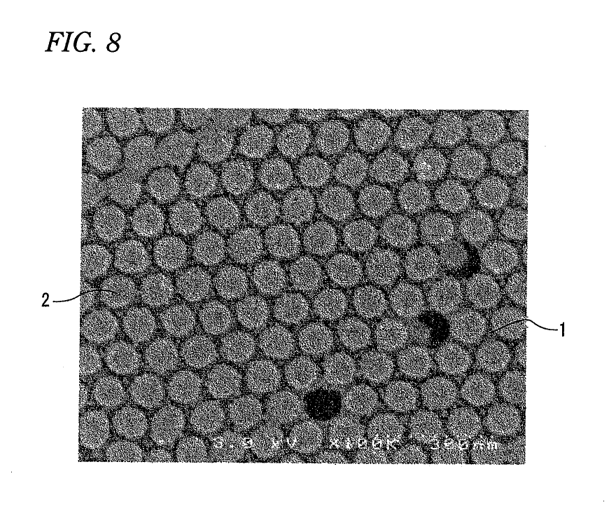

FIG. 8 is a SEM image illustrating surface morphology of the anodized layer 1 where a plurality of linear conductors 3 are provided. The through hole 2 of the linear conductor 3 is filled with a conductive material, and, for example, the linear conductor 3 may have a length of 70 to 180 μm, a diameter of 30 to 1000 nm, and a pitch equal to or higher than 40 nm and equal to or less than 1200 nm. That is, such a fine linear conductor 3 can be formed by filling the through hole 2 of the anodized layer 1 with a conductive material.

Through the aforementioned process, an anodized layer 1 is formed, in which a plurality of linear conductors 3 are densely arranged in parallel with the thickness direction on a plane having a size of approximately 10 mm×10 mm. That is, a plurality of linear conductors 3 are densely arranged in the anodized layer 1 in parallel with one another with an interval smaller than a diameter thereof.

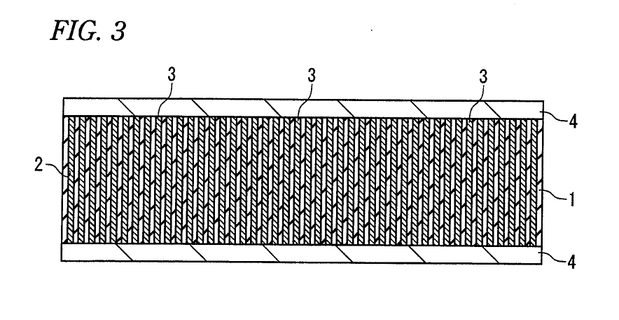

Subsequently, as shown in FIG. 3, a protection layer 4 is formed on each of both surfaces of the anodized layer 1. The protection layer 4 is formed of a metal (such as copper or nickel), for example, through sputtering or plating and has a thickness of approximately 1 μm to 10 μm. While the protection layer 4 is removed in a subsequent process, the protection layer 4 is used to protect (support) a plurality of linear conductors 3 until the protection layer 4 is removed.

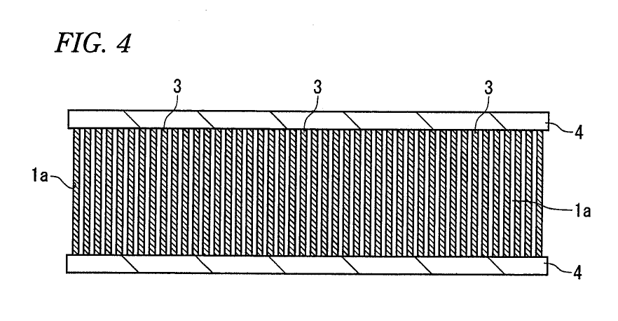

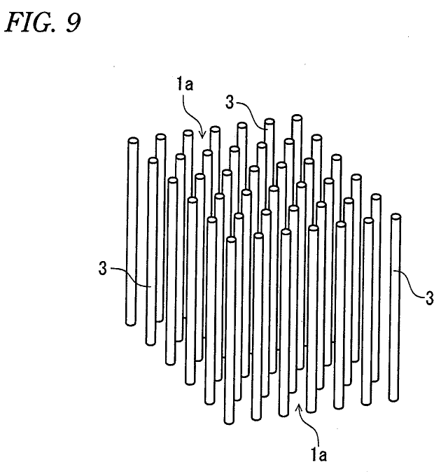

Subsequently, as shown in FIG. 4, a gap la is formed between a plurality of linear conductors 3 by removing the anodized layer 1. For example, it is possible to expose the linear conductors 3 as shown in FIG. 9 by immersing the anodized layer 1 in a sodium hydroxide aqueous solution at a temperature of 50 to 60° C. to etch the anodized layer 1 of aluminum oxide. In FIG. 9, the protection layer 4 is omitted.

Generally, it is known that crystals of an aluminum oxide obtained by anodizing aluminum are called alumina Al₂O₃. Alumina has excellent durability and is highly resistant to acids or alkalis. However, the anodized layer 1 of the present embodiment is not perfect alumina, but the aluminum oxide is a boehmite. Therefore, the anodized layer 1 is vulnerable to alkalis, and the surface of the anodized layer 1 can be easily etched using sodium hydroxide. Subsequently, gaps la can be formed between a plurality of linear conductors 3.

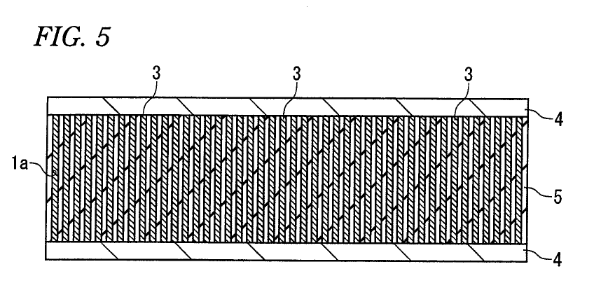

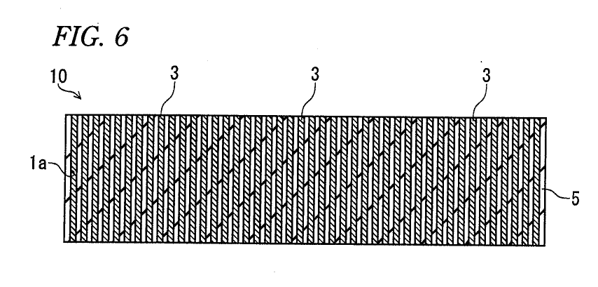

Subsequently, as shown in FIG. 5, the organic insulation layer 5 is formed between the protection layers 4 to fill in between a plurality of linear conductors 3 (gap 1a), and then the protection layer 4 is removed. As a result, it is possible to form the conductive film 10 including the organic insulation layer 5 having a plurality of linear conductors 3 extending therethrough in a thickness direction as shown in FIG. 6. In the conductive film 10, a plurality of linear conductors 3 are exposed from the surface of the organic insulation layer 5 through the organic insulation layer 5. For example, in case where the protection layer 4 is made of copper, the protection layer 4 is removed by using cupric chloride as an etching solution and controlling time to expose the linear conductors 3.

For example, it is possible to form the organic insulation layer 5 to fill the gap 1a by using filler-free epoxy resin (thermosetting resin) having an average molecular length smaller than the gaps between a plurality of linear conductors 3. In addition, the organic insulation layer 5 (the thermosetting resin layer) formed in the respective gaps 1a is formed in an uncured state (in a B-stage state, i.e., a semi-cured state). In case where the organic insulation layer 5 is a thermosetting resin layer in an uncured state, for example, when the connecting terminals of the semiconductor element are connected to the linear conductors 3, the thermosetting resin flows by heating the organic insulation layer 5. Thus, the linear conductor 3 can make contact with the connecting terminal, and mechanical connection can be obtained as described below.

As a result, the organic insulation layer 5 is used as a core layer of the conductive film 10. For example, as shown in FIG. 2, the conductive film may be formed by using the anodized layer 1 which is an inorganic insulation layer as the core layer. However, for example, the connecting member used when an electronic component such as a semiconductor element is packaged on the wiring board requires flexibility and stress distribution. Here, in the present embodiment, the organic insulation layer 5 having a lower elastic modulus than that of the anodized layer 1 (an inorganic insulation layer) is used as the core layer.

The conductive film 10 can be referred to as an anisotropic conductive film because a plurality of the linear conductors 3 are electrically insulated from one another in the thickness direction, and they are anisotropic in the current-flowing direction. In the conductive film 10, the fine linear conductor 3 is formed by filling the through hole 2 of the anodized layer 1 with a conductive material as described above, and thus the conductive film 10 can be used to connect the wiring board to a semiconductor element having a narrow pitch (e.g., 0.1 mm or less) connecting terminal.

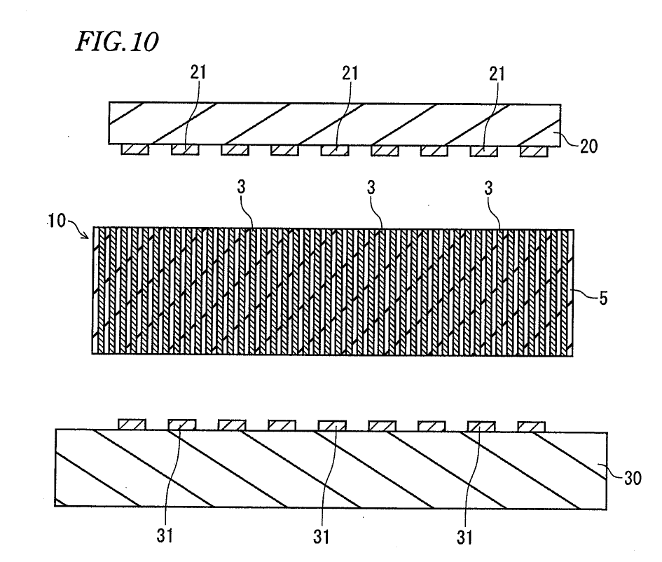

Next, a method of manufacturing a semiconductor device using a conductive film 10 according to the present embodiment will be now described. As shown in FIG. 10, a semiconductor element 20 (chip) including connecting terminals 21 thereon, a wiring board 30 (component) having connecting terminals 31 thereon, and a conductive film 10 are prepared.

The semiconductor element 20 is formed through a known manufacturing technique. In the semiconductor element 20, for example, an element formation surface (main surface) side where an MIS (Metal Insulator Semiconductor) transistor is formed is covered with a passivation film, and the connecting terminals 21 as external connecting terminals are arranged in an area array shape having a pitch equal to or smaller than 100 μm, for example. In addition, in the wiring board 30, the main body is made of a resin, and the outermost surface of a multi-layered structure, for example, formed using a build-up technique is covered by a solder resist layer, and the connecting terminals 31 as external connecting terminals are arranged in an area array shape.

Subsequently, the semiconductor 20 and the wiring board 30 are electrically connected with the conductive film 10 interposed therebetween, and the semiconductor 20 and the wiring board 30 are mechanically bonded to each other. The conductive film 10 according to the present embodiment is obtained by densely arranging a plurality of linear conductors 3 in parallel in a thickness direction within a plane having a size of 10 mm×10 mm. However, at the time of the positioning for packaging, it is not necessary to know in advance which linear conductor 3 is connected to the connecting terminal 21 and the connecting terminal 31.

Then, the semiconductor element 20 having the connecting terminals 21 thereon is disposed on the anodized layer 1, and the linear conductors 3 and the connecting terminals 21 make contact with each other by heating and pressing, and the thermosetting resin layer (the organic insulation layer 5) is cured. In addition, the wiring board 30 having the connecting terminals 31 thereon is arranged on the anodized layer 1, the linear conductors 3 and the connecting terminals 31 make contact with each other by heating and pressing, and the thermosetting resin layer (the organic insulation layer 32) is cured.

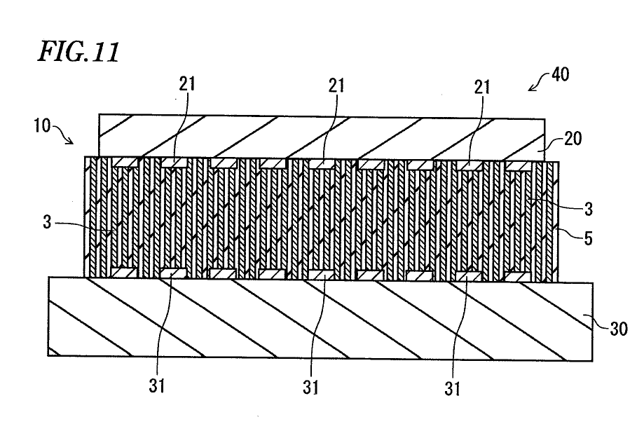

For example, the semiconductor element 20, the conductive film 10, and the wiring board 30 are overlapped with each other between a pair of press heating plates, and it is possible to substantially complete the semiconductor device 40 having an integrated structure as shown in FIG. 11 by heating and pressing from both the upper and lower faces using a vacuum press or the like.

Through such a heating and pressing process, the uncured thermosetting resin layer (the organic resin layer 5) of the conducive film 10 is melted, and the melted resin functions as an underfill resin layer. That is, mechanical bonding among the conductive film 10, the semiconductor element 20, and the wiring board 30 can be obtained by thermally curing the thermosetting resin layer (the organic resin layer 5).

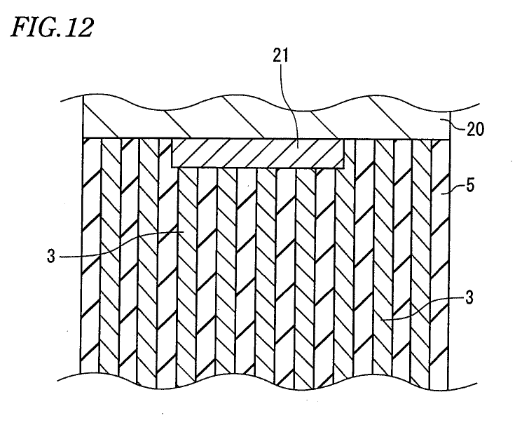

In addition, in the course of the heating and pressing process, as shown in FIG. 12, a bundle of linear conductors 3 among a plurality of linear conductors 3 of the conductive film 10 make contact with the connecting terminals 21 of the semiconductor element 20 and are electrically connected to each other. Similarly, a bundle of linear conductors 3 among a plurality of linear conductors 3 of the conductive film 10 make contact with the connecting terminals 31 of the wiring board 30 and are electrically connected to each other. In this case, due to volume contractibility of the thermally cured thermosetting resin layer (the organic resin layer 5), a contact condition between the connecting terminal 21, 31 and the linear conductor 3 is fixed by the thermosetting resin layer. Therefore, electric connection among the conductive film 10, the semiconductor element 20, and the wiring board 30 is stably maintained.

In this manner, if the conductive film 10A (the conductive film 10) according to the present embodiment is included, it is possible to improve connection reliability and provide a semiconductor device 40 having an improved manufacturing yield.

### Second Embodiment

A method of manufacturing a conductive film according to another embodiment of the present invention will be now described. Firstly, the conductive film 10 is formed through the processes shown in FIGS. 1 to 6 as described in the first embodiment. That is, the conductive film 10 includes the anodized layer 1 having a plurality of linear conductors 3 in parallel in the thickness direction within a plane having a size of 10 mm×10 mm. The linear conductors 3 have a length of 70 μm to 180 μm, a diameter of 30 nm to 1000 nm, and a pitch equal to or higher than 40 nm and equal to or less than 1200 nm. In this manner, in the conductive film 10, a plurality of linear conductors 3 are densely arranged in parallel with one another with a gap smaller than the diameter thereof within the anodized layer 1.

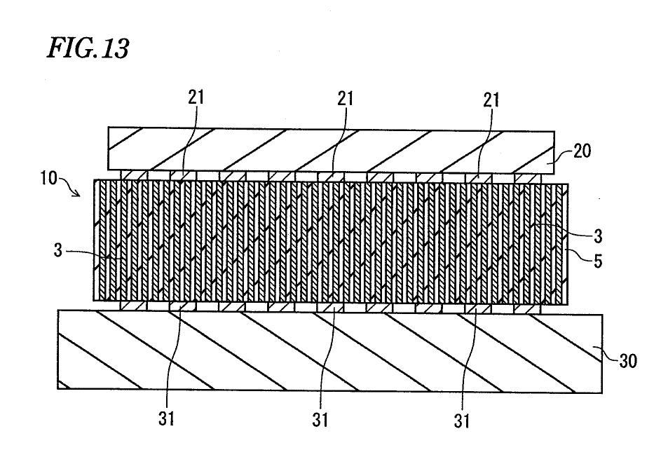

Subsequently, the uncured thermosetting resin layer (the organic resin layer 5) is melted by heating the conductive film 10 and then thermally cured. As a result, it is possible to form the conductive film 10 that includes the organic resin layer 5 having a plurality of linear conductors 3 extending therethrough in the thickness direction, and the surfaces of a plurality of linear conductors 3 are exposed through the organic resin layer 5 (see FIG. 13). In addition, through the thermal curing, it is possible to improve durability of the conductive film 10.

In this regard, in the present embodiment, the elastic modulus of the organic insulation layer 5 of the conductive film 10 is lower than that of the anodized layer 1, which is an inorganic insulation layer, and is equal to or higher than 1 Pa and equal to or lower than 10 MPa. In addition, while the thermosetting resin layer (epoxy resin) is used as the organic insulation layer 5 having such a condition, silicone rubber may also be used.

Such a conductive film 10 may be used as a connecting member which is repeatedly used during an electrical characteristic test process in the manufacturing process of the semiconductor element 20 (the semiconductor device) having a connecting terminals thereon with a narrow pitch. The semiconductor element 20 is formed through a known manufacturing technique. Also, in the semiconductor element 20, for example, an element formation surface (main surface) side where an MIS (Metal Insulator Semiconductor) transistor is formed is covered with a passivation film, and the connecting terminal 21 as an external connecting terminal is arranged in an area array shape (e.g., a pitch equal to or smaller than 100 μm).

In the final process of the semiconductor element 20 or the like, an electric characteristic test is performed for the semiconductor element 20 having connecting terminals 21 with a narrow pitch by interposing the conductive film 10 on the wiring board 30 as shown in FIG. 13. Here, if the conductive film 10 according to the present embodiment is used, it is possible to perform the electric characteristic test even when the semiconductor element 20 has connecting terminals 21 having a narrow pitch, for example, equal to or smaller than 100 μm.

While the present invention has been shown and described with reference to certain exemplary embodiments thereof, other implementations are within the scope of the claims. It will be understood by those skilled in the art that various changes in form and details may be made therein without departing from the spirit and scope of the invention as defined by the appended claims.

What is claimed is:

1. A method of manufacturing a conductive film, the method comprising:
(a) providing an anodized layer having a plurality of through holes extending therethrough in its thickness direction;
(b) forming a plurality of linear conductors by filling each of the through holes with a conductive material;
(c) forming protection layers on both surfaces of the anodized layer;
(d) removing the anodized layer to form a plurality of gaps between the linear conductors;
(e) forming an organic insulation layer between the protection layers to fill the gaps with the organic insulation layer; and
(f) removing the protection layers.

2. A conductive film comprising:
an organic insulation layer; and
a plurality of linear conductors extending through the organic insulation layer in its thickness direction, wherein the linear conductors are exposed from both surfaces of the organic insulation layer, and
wherein the organic insulation layer is an uncured thermosetting resin layer.

3. The conductive film according to claim 2, wherein the thermosetting resin layer is a filler-free epoxy resin.

4. The conductive film according to claim 2, wherein a diameter of the linear conductors is in a range of about 30 nm to about 1000 nm.

5. The conductive film according to claim 2, wherein a pitch of the linear conductors is in a range of about 40 nm to about 200 nm.

6. A semiconductor device comprising:
a semiconductor element having first connecting terminals thereon;
an electrical component having second connecting terminals thereon; and
a conductive film disposed between the semiconductor element and the electrical component to electrically connect the first connecting terminals to the second connecting terminals, the conductive film comprising:
an organic insulation layer; and
a plurality of linear conductors extending through the organic insulation layer in its thickness direction, wherein the linear conductors are exposed from both surfaces of the organic insulation layer, and
wherein the first and second connecting terminals are in contact with the linear conductors and are electrically connected to each other.

7. The semiconductor device according to claim 6, wherein the first and second connecting terminals are embedded in the conductive film.

8. The semiconductor device according to claim 6, wherein the first connecting terminals are disposed between the semiconductor element and the conductive film, and the second connecting terminals are disposed between the electrical component and the conductive film.

9. A method of manufacturing a semiconductor device, the method comprising:
(a) providing an anodized layer having a plurality of through holes extending therethrough in its thickness direction;
(b) forming a plurality of linear conductors by filling each of the through holes with a conductive material;
(c) forming protection layers on both surfaces of the anodized layer;
(d) removing the anodized layer to form a plurality of gaps between the linear conductors;
(e) forming an uncured thermosetting resin layer between the protection layers to fill the gaps with the uncured thermosetting resin layer;
(f) removing the protection layers, thereby forming a conductive film comprising the thermosetting resin layer and the linear conductors; and
(g) providing a semiconductor element having connecting terminals thereon;
(h) disposing the semiconductor element on the conductive film;
(i) heating and pressing the semiconductor element and the conductive film, thereby contacting the linear conductors and the connecting terminals and curing the thermosetting resin layer.
